(19) United States
(12) Patent Application Publication
(10) Pub. No.: US 2018/0287314 A1
(43) Pub. Date: Oct. 4, 2018

(54) MIXED-SIGNAL CONNECTOR AND HIGH-SPEED INTERNAL CABLE ASSEMBLY

(71) Applicant: Intel Corporation, Santa Clara, CA (US)

(72) Inventor: Brent R. Rothermel, Pottstown, PA (US)

(73) Assignee: Intel Corporation, Santa Clara, CA (US)

(21) Appl. No.: 15/475,563

(22) Filed: Mar. 31, 2017

(51) Int. Cl. H01R 24/60; H01B 11/18; H01B 7/08; H01B 11/00; H05K 1/11

(52) U.S. Cl. CPC H01R 24/60; H01B 11/18; H01B 7/04; H01B 11/002; H05K 1/11; H01B 7/08

(57) ABSTRACT

One embodiment provides a mixed signal connector. The mixed signal connector includes a housing, a plurality of housing low-speed electrical contacts and a plurality of mixed-signal connector electrical contacts. The plurality of housing low-speed electrical contacts are to removably couple to a number of substrate electrical contacts. The plurality of mixed-signal connector electrical contacts are to removably couple to an external cable assembly. The plurality of mixed-signal connector electrical contacts includes a first subset to fixedly couple to a high-speed internal cable, and a second subset coupled to the plurality of housing low-speed electrical contacts.

### FIELD

The present disclosure relates to a connector and a cable assembly, in particular to, a mixed-signal connector and high-speed internal cable assembly.

### BACKGROUND

A data center may include a number of servers and a number of network switches. Each server and each network switch may be contained in an enclosure. Inside a corresponding enclosure, high-speed cabling interconnects may be utilized between a processor and a faceplate of a server and/or between switch circuitry and a faceplate of a switch device. Each faceplate may be positioned in, on and/or adjacent to the corresponding enclosure.

Each high-speed cabling interconnect may include a first connector at a first end, a second connector at a second end and a high-speed cable, e.g., twinaxial cable (“Twinax”), coupled between the first connector and the second connector. The first connector is configured to couple to the processor via a processor connector or to switch circuitry via a switch connector. The second connector is configured to couple to a faceplate connector. The faceplate connector is configured to receive an external connector that is coupled to an external cable (external to the enclosure). The faceplate connector may be further configured to couple power and sideband signals between the server or switch device and the external cable assembly.

The high-speed cabling interconnect may thus be separable from the processor or switch circuitry at the first end and separable from the faceplate connector at the second end. Such separability is configured to facilitate serviceability. Each pair of mating connectors, e.g., the second connector/faceplate connector pair, in a signal path may degrade very high-speed signals. Each pair of mating connectors may thus reduce the distance from a source (e.g., processor, switch circuitry) at which a recoverable signal may be received. Lower frequency signals may be generally less susceptible to such degradation.

### BRIEF DESCRIPTION OF DRAWINGS

Features and advantages of the claimed subject matter will be apparent from the following detailed description of embodiments consistent therewith, which description should be considered with reference to the accompanying drawings, wherein:

FIGS. 1A through 1D illustrate four example mixed-signal systems, consistent with several embodiments of the present disclosure;

FIGS. 2A, 2B and 2C illustrate section views of the mixed-signal connectors of the four example mixed-signal systems of FIGS. 1A through 1D;

FIGS. 3A and 3B illustrate end views of a mixed-signal connector and an external connector, respectively, consistent with several embodiments of the present disclosure; and

FIG. 4 illustrates a server platform, consistent with several embodiments of the present disclosure.

Although the following Detailed Description will proceed with reference being made to illustrative embodiments, many alternatives, modifications, and variations thereof will be apparent to those skilled in the art.

### DETAILED DESCRIPTION

Generally, this disclosure relates to a mixed-signal connector and a high-speed internal cable assembly, consistent with several embodiments of the present disclosure. The mixed signal connector may include a housing, a plurality of housing low-speed electrical contacts and a plurality of mixed-signal connector electrical contacts. The plurality of mixed-signal connector electrical contacts are configured to removably couple to an external cable assembly. The plurality of housing low-speed electrical contacts are configured to removably couple to a number of substrate electrical contacts.

The plurality of mixed-signal connector electrical contacts may include a first subset and a second subset. The first subset is configured to fixedly couple to a high-speed internal cable. The second subset are coupled to the plurality of housing low-speed electrical contacts. The second subset of mixed-signal connector electrical contacts are thus configured to be removably coupled to the number of substrate electrical contacts via the housing low-speed electrical contacts. Thus, the first subset may include at least one high-speed mixed-signal connector electrical contact and the second subset may include at least one low-speed mixed-signal connector electrical contact. The second subset may further include a power mixed-signal connector electrical contact.

The high-speed internal cable assembly includes a high-speed internal cable having a first end and a second end. The high-speed internal cable assembly further includes a device connector and a mixed-signal connector, consistent with the present disclosure. The device connector is fixedly coupled to the high-speed internal cable at the first end. The mixed-signal connector is fixedly coupled to the high-speed internal cable at the second end.

The high-speed internal cable is configured to carry relatively high-speed signals, for example, with data rates of 25 Gb per second and greater. The mixed-signal connector is configured to removably couple to a substrate. The substrate may contain one or more conductive elements configured to carry relatively low-speed signals and/or power. For example, the substrate may correspond to a printed circuit board (PCB) and the conductive elements may correspond to PCB traces.

As used herein, “fixedly couple” and/or “fixedly coupled” means coupled at manufacturing and not meant to be routinely decoupled for, for example, field service. Examples of fixedly coupled may include, but are not limited to, soldered, crimped, welded, etc. As used herein, “removably couple” and/or “removably coupled” means may be decoupled for, for example, field service, maintenance and/or replacement. Examples of elements that may be removably coupled include, but are not limited to, mating connectors (e.g., plug and socket), a connector and receptacle configured to receive the connector, a removable mechanical feature (e.g., fastener, latch, screw, clip, clamp, strap, bracket, holddown mechanism, etc.), etc. As used herein, “couple” means fixedly or removably couple and “coupled” means fixedly or removably coupled.

As used herein, “mixed-signal” means a combination of at least a high-speed signal and a low-speed signal. Mixed-signal may further include power. Power may include a supply power (e.g., a direct current (DC) voltage and/or current) and/or ground. High-speed signals are signals with data rates of on the order of 10 Gigabits per second (Gbps) or greater, e.g., 25 Gbps, 100 Gbps, etc. Low-speed signals are signals with data rates of on the order of one Gbps or less, e.g., 100 Megabits per second (Mbps), 3.5 Mbps, 3.2 Mbps, 1 Mbps, 400 kilobits per second (kbps), 100 kbps, etc. Thus, a data rate of a high-speed signal is greater than a data rate of a low-speed signal. A mixed-signal connector may thus be configured to carry at least one high-speed signal and at least one low-speed signal. A mixed-signal connector may be further configured to carry power.

In an embodiment, the device connector may be configured to couple to a processor via a processor connector. In another embodiment, the device connector may be configured to couple to switch circuitry via a switch connector. The switch connector may be coupled to the switch circuitry via, for example, PCB traces.

In an embodiment, the mixed-signal connector may be removably coupled to the substrate by a mechanical feature, e.g., a fastener, a latch, a screw, a clip, a clamp, a strap, a bracket, a holddown mechanism, etc. In this embodiment, each housing low-speed electrical contact (including a power electrical contact) may be configured to electrically couple (e.g., connect) to a respective PCB trace via a respective substrate electrical contact, for example a conductive pad positioned on a surface of the PCB.

In another embodiment, the mixed-signal connector may be removably coupled to the substrate by a receptacle. In this embodiment, the receptacle may be fixedly coupled to the substrate and is configured to receive the mixed-signal connector. The receptacle is configured to mechanically and electrically removably couple to the mixed-signal connector. The mixed-signal connector housing and/or receptacle may include one or more mechanical features configured to provide the removable mechanical coupling. The receptacle may include a plurality of receptacle-connector electrical contacts configured to removably couple to housing low-speed electrical contacts (including a power electrical contact). The receptacle may further include a plurality of receptacle-substrate electrical contacts configured to fixedly couple to substrate electrical contacts.

In another embodiment, the mixed-signal connector may be removably coupled to a faceplate. In this embodiment, each housing low-speed electrical contact (including a power electrical contact) may be coupled to a first end of a respective low-speed conductor, e.g., a wire. A respective second end of each wire may be removably coupled to a corresponding substrate electrical contact. For example, each wire may terminate, at the respective first end, in a connector configured to mate with a housing low-speed electrical connector and may terminate, at the respective second end, in an intermediate connector configured to removably couple to a low-speed PCB connector fixedly coupled to the substrate. In this embodiment, the mixed-signal connector may be positioned a distance, D, from a surface of the substrate.

Thus, the high-speed internal cable assembly may be removably coupled at a first end to the processor or switch device and may be removably coupled at a second end to an external cable assembly. Fixedly coupling the high-speed cable to the device connector and to the mixed-signal connector is configured to reduce and/or minimize one or more sources of signal degradation in the high-speed signal path. Removably coupling the mixed-signal connector to the substrate is configured to facilitate serviceability of the high-speed internal cable assembly and/or associated server board or switch board (e.g., installation and/or removal of the high-speed internal cable assembly and/or associated board).

Thus, a mixed-signal system consistent with several embodiments of the present disclosure may be configured to optimize performance, serviceability and cost. High-speed signals may be carried by a high-speed internal cable assembly, as described herein, and low-speed signals and/or power may be carried by PCB traces. A number of connectors in the high-speed signal path may be constrained (e.g., reduced) by fixedly coupling the high-speed internal cable to the mixed-signal connector. Serviceability may be maintained by configuring the mixed-signal connector to removably couple to the substrate. A low-speed and/or power signal path may be relatively less sensitive to the removable mixed-signal connector compared to a high-speed signal path. In other words, the signal integrity of the low-speed path is relatively easier to maintain than the signal integrity of the high-speed path due to a relatively lower bit rate of the low-speed signals compared to a bit rate of the high-speed signals.

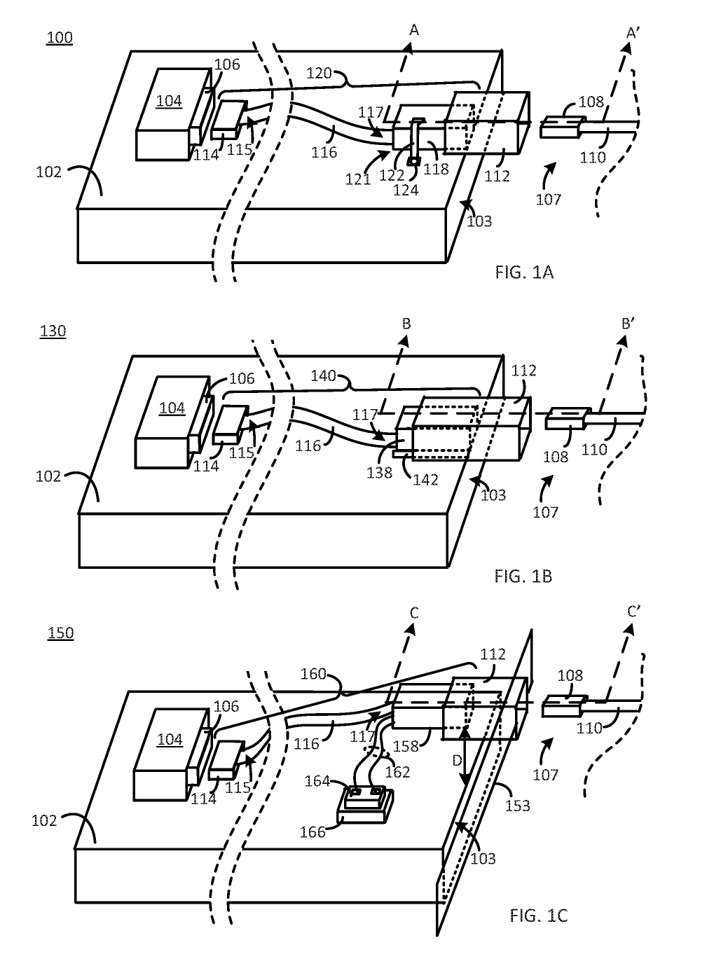

FIGS. 1A through 1D illustrate four example mixed-signal systems 100, 130, 150, 170, consistent with several embodiments of the present disclosure. It may be appreciated that the example mixed-signal systems 100, 130, 150, 170 are simplified to facilitate description of the high-speed internal cable assemblies 120, 140, 160, 180. Thus, the example mixed-signal systems 100, 130, 150, 170 may include other circuit elements (not shown), consistent with the present disclosure.

Each example mixed-signal system 100, 130, 150, 170 includes a substrate 102, a respective high-speed internal cable assembly 120, 140, 160, 180, a cage 112 and an external cable assembly 107. The external cable assembly 107 includes an external mating connector 108 and an external cable 110. The substrate 102 may correspond to, for example, a printed circuit board (PCB). The substrate 102 may thus contain one or more conductive traces, as described herein. The cage 112 is configured to facilitate alignment of the external mating connector 108 with a corresponding mixed-signal connector, as described herein. The cage 112 is further configured to provide electromagnetic interference (EMI) mitigation, i.e., containment. The cage 112 may be positioned relative to an edge 103 of the PCB 102. For example, the edge 103 and cage 112 may be positioned relative to a faceplate and/or an enclosure, e.g., a server enclosure or a switch device enclosure.

Example mixed-signal systems 100, 130, 150 further include a processor 104 and a processor connector 106. Example mixed-signal system 170 further includes switch circuitry 174 and a switch connector 176. Descriptions of the mixed-signal connector included in each respective high-speed internal cable assembly 120, 140, 160, 180 may apply to a mixed-signal system (e.g., mixed-signal systems 100, 130, 150) that includes a processor, e.g., processor 104 and/or a mixed-signal system (e.g., mixed-signal system 170) that includes switch circuitry, e.g., switch circuitry 174, consistent with the present disclosure.

In an embodiment, processor connector 106 may correspond to a PCB edge connector. In another embodiment, processor connector 106 may correspond to a plurality of electrical contacts (e.g., gold fingers) positioned on an edge of the processor 104 substrate. In this embodiment, the plurality of electrical contacts, may be termed a “one-piece card-edge style connector”, where the one-piece corresponds to a mating connector, e.g., device connector 114, as described herein.

Turning now to FIG. 1A, example high-speed internal cable assembly 120 includes a device connector 114, a high-speed internal cable 116 and a mixed-signal connector 118. The high-speed internal cable 116 has a first end 115 and a second end 117. The high-speed internal cable 116 may include, but is not limited to, twinaxial cable (“Twinax”), a flexible PCB and/or a flexible flat cable. The high-speed internal cable is configured to contain at least one conductor pair. Device connector 114 may be fixedly coupled to the high-speed internal cable 116 at the first end 115. Mixed-signal connector 118 may be fixedly coupled to the high-speed internal cable 116 at the second end 117. Device connector 114 is configured to removably couple to processor connector 106. Mixed-signal connector 118 is configured to removably couple to PCB 102. External connector 108 is configured to removably couple to mixed-signal connector 118.

Example mixed-signal system 100 may further include a removable mechanical feature 121 configured to removably couple mixed-signal connector 118 to PCB 102. Removable mechanical feature 121 includes a removable holddown mechanism 122 and a removable fastener 124. Removable holddown mechanism 122 may include, but is not limited to, to a latch, a clip, a clamp, a strap, a bracket, etc. Fastener 124 is configured to removably couple removable holddown mechanism 122 to PCB 102. Fastener 124 may include, but is not limited to, a screw, a clip, a tab, etc. Removable mechanical feature 121 is configured to mechanically couple the mixed-signal connector 118 to the PCB 102.

When the mixed-signal connector 118 is mechanically coupled to the PCB 102, a plurality of housing low-speed electrical contacts (including a power electrical contact) included in mixed-signal connector 118 are configured to be electrically coupled to substrate electrical contacts, e.g., conductive pads, that are connected to corresponding PCB traces, as described herein. Thus, when the mixed-signal connector 118 is mechanically coupled to the substrate 102, low-speed signals and/or power may be coupled to a subset of mixed-signal connector 118 electrical contacts, as described herein. The subset of mixed-signal connector 118 electrical contacts may then be coupled to external cable assembly 107 when the external connector 108 is coupled to mixed-signal connector 118.

Turning now to FIG. 1B, similar to example high-speed internal cable assembly 120 of FIG. 1A, example high-speed internal cable assembly 140 includes device connector 114 that may be fixedly coupled to the high-speed internal cable 116 at the first end 115. Example high-speed internal cable assembly 140 further includes a mixed-signal connector 138 that may be fixedly coupled to the high-speed internal cable 116 at the second end 117.

Example mixed-signal system 130 may further include a receptacle 142. Receptacle 142 may be fixedly coupled to PCB 102. Receptacle 142 is configured to receive mixed-signal connector 138. Mixed-signal connector 138 is configured to removably couple to receptacle 142. Receptacle 142 is configured to provide both electrical and mechanical coupling between mixed-signal connector 138 and PCB 102 when mixed-signal connector 138 is coupled to receptacle 142. Receptacle 142 is thus configured to provide removable electrical coupling between housing low-speed and/or power electrical contacts included in mixed-signal connector 138 and corresponding substrate low-speed and/or power electrical contacts included in PCB 102, as described herein. When the mixed-signal connector 138 is removably mechanically coupled to receptacle 142, the housing low-speed electrical contacts included in mixed-signal connector 138 are configured to be electrically coupled via receptacle 142 to the substrate low-speed and/or power electrical contacts, as described herein. Thus, when the mixed-signal connector 138 is mechanically coupled to receptacle 142, relatively low-speed signals and/or power may be coupled to a subset of mixed-signal connector 138 electrical contacts. The subset of mixed signal connector 138 electrical contacts may then be coupled to the external cable assembly 107 when the external connector 108 is coupled to mixed-signal connector 138.

Turning now to FIG. 1C, similar to example high-speed internal cable assembly 120 of FIG. 1A, example high-speed internal cable assembly 160 includes device connector 114 that may be fixedly coupled to the high-speed internal cable 116 at the first end 115. Example, mixed-signal system 150 may further include a faceplate 153. Example high-speed internal cable assembly 160 further includes a mixed-signal connector 158 that may be fixedly coupled to the high-speed internal cable 116 at the second end 117. In this example mixed-signal system 150, mixed-signal connector 158 is configured to be positioned a distance, D, from PCB 102. The mixed-signal connector 158 may then be coupled to the faceplate 153. For example, faceplate 153 may correspond to a faceplate of a server board. In other words, in this example system 150, the mixed-signal connector 158 may not be positioned on the PCB 102.

Example mixed-signal system 150 further includes one or more low-speed conductors (e.g., wires) 162, low-speed intermediate connector 164 and low-speed PCB connector 166. Low-speed conductors 162 are configured to couple low-speed intermediate connector 164 to housing low-speed electrical contacts included in mixed-signal connector 158, as described herein. Low-speed PCB connector 166 may be fixedly coupled to PCB 102. Low-speed intermediate connector 164 may be removably coupled to low-speed PCB connector 166. Low-speed PCB connector 166 may be electrically coupled to substrate electrical contacts and/or corresponding PCB traces configured to carry low-speed signals and/or power signals. When the low-speed intermediate connector 164 is mechanically coupled to the low-speed PCB connector 166, housing low-speed electrical contacts included in mixed-signal connector 158 are configured to be electrically coupled via a combination of low-speed conductors 162, electrical contacts included in low-speed intermediate connector 164 and electrical contacts included in low-speed PCB connector 166 to corresponding substrate low-speed electrical contacts and/or PCB traces, as described herein. Thus, when the low-speed intermediate connector 164 is mechanically coupled to the low-speed PCB connector 166, a number of substrate low-speed electrical contacts may be coupled to a subset of mixed-signal connector 158 electrical contacts. The subset of mixed-signal connector 158 electrical contacts may then be coupled to external cable assembly 107 when the external connector 108 is coupled to mixed-signal connector 138.

Turning now to FIG. 1D, example mixed-signal system 170 includes switch circuitry 174, a switch connector 176 and the high-speed internal cable assembly 180. Similar to the example high-speed internal cable assembly 140 of FIG. 1B, the example high-speed internal cable assembly 180 includes the high-speed internal cable 116 and the mixed-signal connector 138 that may be fixedly coupled to the high-speed internal cable 116 at the second end 117. Similar to example mixed-signal system 130 of FIG. 1B, example mixed-signal system 170 includes receptacle 142 that may be fixedly coupled to PCB 102 and is configured to receive mixed-signal connector 138.

Example high-speed internal cable assembly 180 further includes a device connector 184 that may be fixedly coupled to high-speed internal cable 116 at the first end 115. The device connector 184 is configured to removably couple to switch connector 176. Switch connector 176 may be coupled to switch circuitry 174 by a plurality of PCB traces included in PCB 102. Switch circuitry 174 may be similarly coupled to the plurality of PCB traces. Thus, in this example, example high-speed internal cable assembly 180 may be coupled to switch circuitry 174 via switch connector 176 and a plurality of PCB traces.

Example mixed-signal system 170 has been described with respect to a switch circuitry. A similar configuration may be implemented with a processor rather than switch circuitry. In other words, a processor connector corresponding to switch connector 176 and configured to couple to a device connector (e.g., device connector 184), may be coupled to the processor via a plurality of PCB traces, within the teachings of the present disclosure.

Thus, a mixed-signal connector may be fixedly coupled to a high-speed internal cable configured to carry relatively high-speed signals and removably coupled to a substrate, e.g., PCB, that includes one or more traces configured to carry relatively low-speed signals and/or power. Thus, transmission of high-speed signals between a source device (e.g., processor, switch circuitry) and an external cable assembly may be facilitated and ease of assembly, disassembly, service and/or maintenance of a server and/or switch device may be maintained.

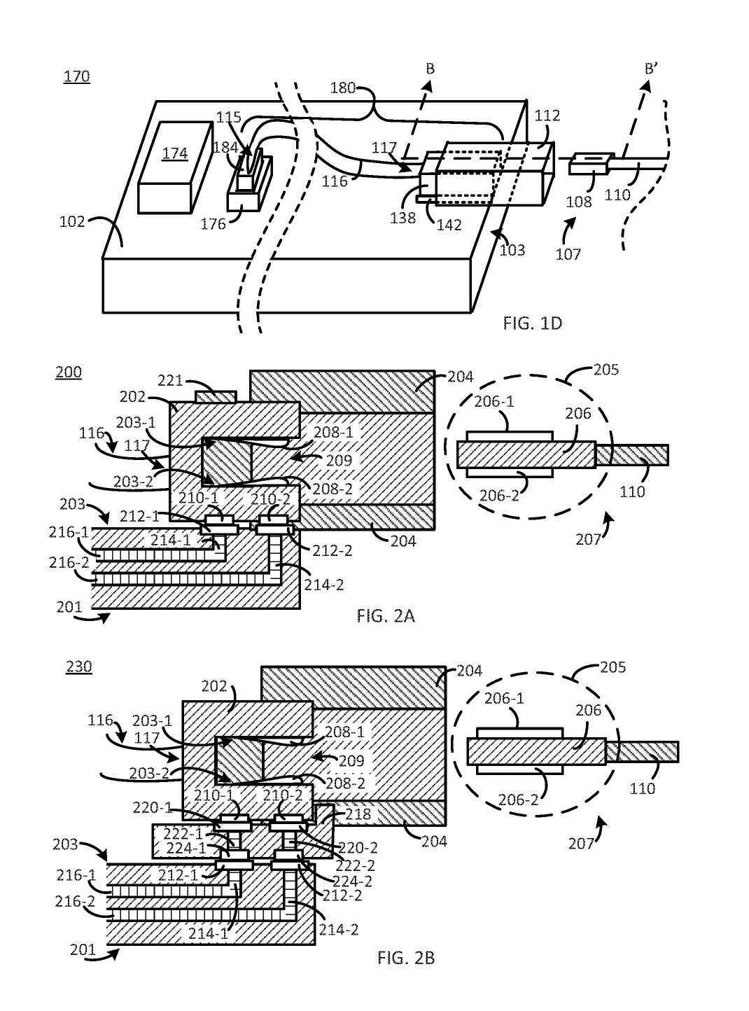

FIGS. 2A, 2B and 2C illustrate section views 200, 230, 250, that include the mixed-signal connectors of the four example mixed-signal systems of FIGS. 1A through 1D. FIGS. 2A, 2B and 2C may be best understood when considered together. FIG. 2A corresponds to section view A-A′ of FIG. 1A. FIG. 2B corresponds to section view B-B′ of FIG. 1B. FIG. 2B further corresponds to section view B-B′ of FIG. 1D. FIG. 2C corresponds to section view C-C′ of FIG. 1C. Section views 200, 230, 250 generally illustrate electrical coupling between a mixed-signal connector (e.g., a plurality of housing low-speed electrical contacts included in the mixed-signal connector) and substrate electrical contacts when the mixed-signal connector is mechanically coupled to the substrate, e.g., PCB. The substrate electrical contacts are electrically coupled to electrical conductors (e.g., PCB traces) included in the PCB. The housing low-speed electrical contacts are coupled to a subset of mixed signal connector electrical contacts.

Each section view 200, 230, 250 includes the first end 117 and a portion of the high-speed internal cable 116, a mixed-signal connector housing 202, a cage 204 and an external cable assembly 207. The mixed-signal connector housing 202 defines an opening 209 configured to receive at least a portion of the external cable assembly 207.

The external cable assembly 207 includes an external connector 205 and the external cable 110. The external connector 205 includes an external connector substrate 206 and a plurality of electrical contacts, e.g., external connector electrical contacts 206-1 and 206-2. The external connector substrate 206 may include, but is not limited to, a PCB, a connector plug, etc. External connector electrical contacts 206-1 and 206-2 are positioned on opposing surfaces of the external connector substrate 206. In an embodiment, the external connector electrical contacts 206-1, 206-2 may be conductive pads. Of course, in other embodiments, the external connector electrical contacts may include other external connector conductive material configurations configured to electrically couple to a plurality of mixed-signal connector electrical contacts when the external connector 205 is inserted in the mixed-signal connector opening 209, as described herein.

Each section view 200, 230, 250 further includes a plurality of mixed-signal connector electrical contacts, e.g., mixed-signal connector electrical contacts 208-1 and 208-2, positioned on opposing internal surfaces 203-1, 203-2 of the mixed-signal connector housing 202. The mixed-signal connector electrical contacts, e.g., mixed-signal connector electrical contacts 208-1 and 208-2, are configured to removably couple to the external cable assembly 207 via external connector electrical contacts, e.g., external connector electrical contacts 206-1, 206-2. The mixed-signal connector electrical contacts 208-1, 208-2 may be compliant and configured to deform when the external electrical connector 205 is inserted in the mixed-signal connector housing 204 opening 209. Each mixed-signal connector electrical contact 208-1, 208-2 may be configured to align with a respective external connector electrical contact 206-1, 206-2 when the external connector 205 is inserted into the opening 209. Cage 204 may facilitate alignment of external connector 205 and mixed-signal connector housing 202.

Section views 200 and 230 each further include a plurality of housing low-speed electrical contacts (including a power electrical contact), e.g., housing low-speed electrical contacts 210-1 and 210-2. The housing low-speed electrical contacts 210-1, 210-2 may be positioned in and/or on an external surface, e.g., bottom surface, of the mixed-signal connector housing 202. The housing low-speed electrical contacts 210-1, 210-2 may each be electrically coupled to respective mixed-signal connector electrical contacts, e.g., mixed-signal connector electrical contacts 208-1, 208-2, within mixed-signal connector housing 202.

Section views 200 and 230 each further include a cross-section 201 of PCB 102 of FIG. 1. Cross-section 201 includes a plurality of conductive trace portions, e.g., conductive trace portions 216-1 and 216-2, and a respective via 214-1, 214-2 coupled to each conductive trace portion 216-1, 216-2. Section views 200 and 230 each further include a plurality of electrical contacts, e.g., substrate electrical contacts 212-1 and 212-2, positioned on a top surface 203 of the cross-section 201 of PCB 102. Each substrate electrical contact 212-1, 212-2 is coupled to a respective conductive trace 216-1, 216-2 by a respective via 214-1, 214-2. For example, conductive traces 216-1, 216-2 may be configured to carry low-speed signals from a source device (e.g., a processor and/or switch circuitry) and/or power from a power source to substrate electrical contacts 212-1, 212-2.

Turning now to FIG. 2A, in this example section view 200, the mixed-signal connector housing 202 may be removably coupled directly to substrate 201. In other words, a receptacle may not be utilized. Section view 200 further includes a portion 221 of a mechanical feature configured to removably mechanically couple the housing 202 to the substrate 201. The housing low-speed electrical contacts 210-1, 210-2 may be coupled to substrate electrical contacts, e.g., substrate electrical contacts 212-1, 212-2, when the corresponding mixed-signal connector, e.g., mixed signal connector 118, 138, is mechanically coupled to the corresponding substrate, e.g., PCB 102 of FIGS. 1A, 1B, 1D.

Turning now to FIG. 2B, section view 230 further includes a receptacle 218. The receptacle 218 corresponds to receptacle 142 of FIGS. 1B, 1D. The receptacle 218 may be fixedly coupled to the substrate portion 201 at a top surface 203. Section view 230 further includes a plurality of receptacle-connector electrical contacts, e.g., receptacle-connector electrical contacts 220-1, 220-2, and a plurality of receptacle-substrate electrical contacts, e.g., receptacle-substrate electrical contacts 224-1, 224-2. Each receptacle-connector electrical contact 220-1, 220-2 is coupled to a respective receptacle-substrate electrical contact 224-1, 224-2 by a respective via, e.g., vias 222-1, 222-2.

The receptacle 218 may be fixedly coupled to substrate 201 at the top surface 203 of the substrate 201. The receptacle-substrate electrical contacts 224-1, 224-2 may be electrically coupled to respective substrate electrical contacts 212-1, 212-2 when the receptacle 218 is coupled to substrate 201. The mixed-signal connector housing 202 may be removably coupled to receptacle 218. The housing low-speed electrical contacts 210-1, 210-2 may be electrically coupled to receptacle-connector electrical contacts 220-1, 220-2 when the mixed-signal connector housing 202 is coupled to receptacle 218. The plurality of housing low-speed electrical contacts, e.g., housing low-speed electrical contacts 210-1, 210-2, may then be removably coupled to respective substrate electrical contacts 212-1, 212-2. A subset of mixed-signal connector electrical contacts, e.g., mixed-signal connector electrical contacts 208-1, 208-2, may then be removably coupled to respective substrate electrical contacts 212-1, 212-2.

Turning now to FIG. 2C, section view 250 includes a plurality of low-speed conductors, e.g., low-speed conductors 256-1, 256-2, a plurality of low-speed conductor electrical contacts, e.g., low-speed conductor electrical contacts 254-1, 254-2, and a plurality of housing low-speed electrical contacts (including a power electrical contact), e.g., housing low-speed electrical contacts 252-1, 252-2. Low-speed conductors 256-1, 256-2 may correspond to conductors (e.g., wires) 162 of FIG. 1C. The housing low-speed electrical contacts 252-1, 252-2 may be defined in housing 202 and are configured to receive low-speed conductors 256-1, 256-2 and/or low-speed conductor electrical contacts 254-1, 254-2. The low-speed conductors 256-1, 256-2 may be removably or fixedly coupled to housing low-speed electrical contacts 252-1, 252-2, respectively. Housing low-speed electrical contacts 252-1, 252-2 may be electrically coupled to a subset of mixed-signal connector electrical contacts, e.g., mixed-signal electrical contacts 208-1, 208-2, within housing 202.

Thus, when the external connector 205 is inserted in the opening 209 in mixed-signal connector housing 202, external connector electrical contacts 206-1, 206-2 may be electrically coupled, via mixed-signal connector electrical contacts 208-1, 208-2, to the high-speed internal cable 116 and to a plurality of housing low-speed electrical contacts, e.g., housing electrical contacts 252-1, 252-2. A subset of the external connector electrical contacts may then be removably coupled, via housing low-speed electrical contacts 252-1, 252-2, to a number of substrate electrical contacts, e.g., 212-1, 212-2.

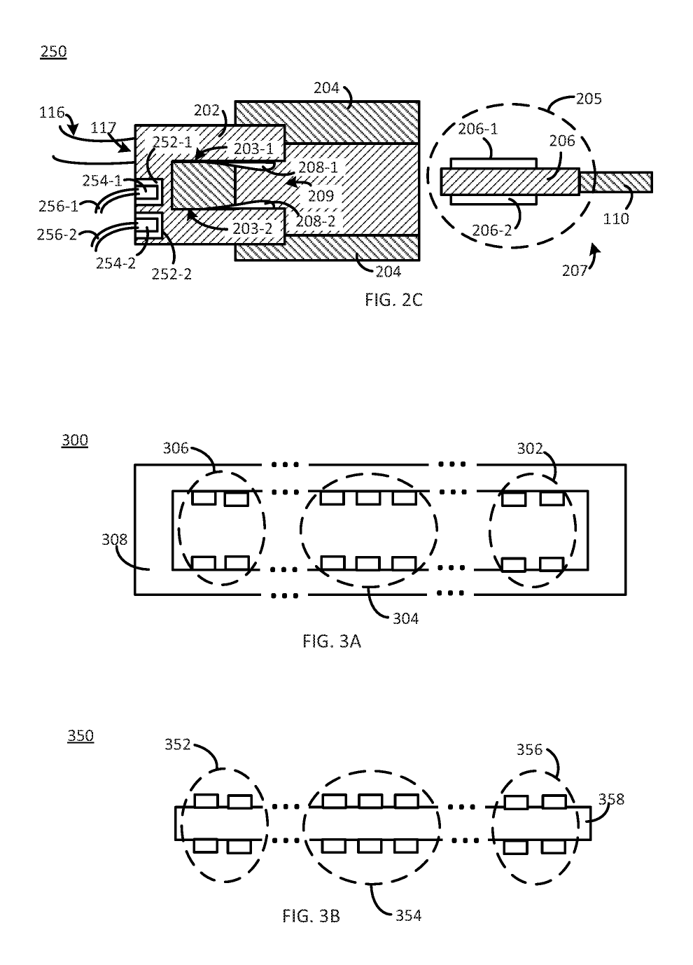

FIGS. 3A and 3B illustrate end views of a mixed-signal connector 300 and an external connector 350, respectively, consistent with several embodiments of the present disclosure. The external connector 350 is configured to mate with the mixed-signal connector 300.

Turning now to FIG. 3A, mixed-signal connector 300 includes a housing 308 and a plurality of mixed-signal connector electrical contacts. The plurality of mixed-signal electrical contacts includes a first subset 302, a second subset 304 and a third subset 306. The first subset 302 of mixed-signal electrical contacts may correspond to transmit mixed-signal connector high-speed electrical contacts configured to carry high-speed signals transmitted by, e.g., a processor and/or switch circuitry. The third subset 306 of mixed-signal electrical contacts may correspond to receive mixed-signal connector high-speed electrical contacts configured to carry high-speed signals received from an external cable assembly. The first subset 302 of mixed-signal electrical contacts and third subset 306 of mixed-signal electrical contacts may be fixedly coupled to a high-speed internal cable when mixed-signal connector 300 is included in a high-speed internal cable assembly, as described herein. For example, each transmit mixed-signal connector high-speed electrical contact of the first subset 302 and each receive mixed-signal connector high-speed electrical contact of the third subset 306 may be coupled to a respective high-speed conductor, e.g., included in a twinaxial cable, a flexible PCB or a flexible flat cable.

The second subset 304 of mixed-signal connector electrical contacts may correspond to mixed-signal connector low-speed electrical contacts. The second subset 304 of mixed-signal connector electrical contacts, i.e., the mixed-signal connector low-speed electrical contacts, may further include one or more power mixed-signal electrical contacts. The second subset 304 of mixed-signal connector electrical contacts may be configured to be removably coupled to a number of substrate electrical contacts. For example, each mixed-signal connector low-speed electrical contact of the second subset 304 may be coupled to a respective housing low-speed electrical contact, as described herein.

Turning now to FIG. 3B, external connector 350 includes a connector substrate 358 and a plurality of external connector electrical contacts. The plurality of external connector electrical contacts may include a first subset 352, a second subset 354 and a third subset 356. The first subset 352 of external connector electrical contacts may correspond to transmit external connector high-speed electrical contacts configured to carry high-speed signals transmitted by, e.g., a processor and/or switch circuitry. The third subset 356 of external connector electrical contacts may correspond to receive external connector high-speed electrical contacts configured to carry high-speed signals received from an external cable. A second subset 354 of external connector electrical contacts may correspond to external connector low-speed electrical contacts.

The first subset 352 of external connector electrical contacts may be configured to couple to the first subset 302 of mixed-signal electrical contacts when the external connector 350 is coupled to, i.e., inserted in, the mixed-signal connector 300. In other words, the first subset 352 of external connector electrical contacts may be configured to align with the first subset 302 of mixed-signal electrical contacts. The second subset 354 of external connector electrical contacts may be configured to couple to the second subset 304 of mixed-signal electrical contacts when the electrical connector 350 is coupled to the mixed-signal connector 300. The second subset 354 of external connector electrical contacts may be configured to align with the second subset 304 of mixed-signal electrical contacts. The third subset 356 of external connector electrical contacts may be configured to couple to the third subset 306 of mixed-signal electrical contacts when the electrical connector 350 is coupled to the mixed-signal connector 300. The third subset 356 of external connector electrical contacts may be configured to align with the third subset 306 of mixed-signal electrical contacts.

Thus, a mixed signal connector may include a housing, a plurality of housing low-speed electrical contacts (including a power electrical contact) and a plurality of mixed-signal connector electrical contacts. The plurality of housing low-speed electrical contacts are configured to removably couple to a number of substrate electrical contacts. The mixed-signal connector electrical contacts are configured to removably couple to an external cable assembly. The plurality of mixed-signal connector electrical contacts may include a first subset and a third subset configured to fixedly couple to a high-speed internal cable. The plurality of mixed-signal connector electrical contacts may further include a second subset. The second subset may be coupled to the plurality of housing low-speed electrical contacts (including a power electrical contact). The second subset of mixed-signal connector electrical contacts are thus configured to be removably coupled to the number of substrate electrical contacts.

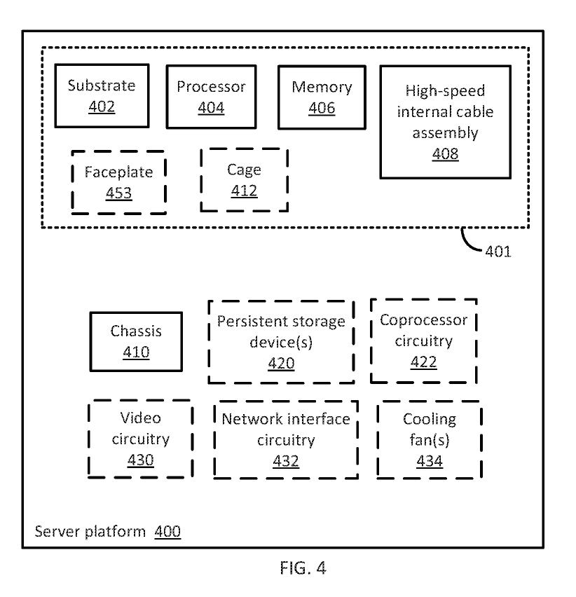

FIG. 4 illustrates a server platform 400, consistent with several embodiments of the present disclosure. Server platform 400 includes a substrate 402, a processor 404, a memory 406 and a high-speed internal cable assembly 408. Server platform 400 may include chassis 410, a cage 412 and/or a faceplate 453. In some embodiments, server platform 400 may further include at least one of a persistent storage device 420 and/or a coprocessor circuitry 422. In some embodiments, server platform 400 may further include one or more of a video circuitry 430, a network interface circuitry 432 and/or a cooling fan 434.

For example, processor 404 may correspond to a single core or a multi-core general purpose processor, such as those provided by Intel® Corp., etc. For example, persistent storage may include, but is not limited to, a hard disk drive, a solid state drive, NAND flash memory, etc. For example, coprocessor circuitry may include, but is not limited to, a graphics processing unit, a digital signal processing unit, etc.

Substrate 402 corresponds to substrate (e.g., PCB 102), processor 404 corresponds to processor 104 and cage 412 corresponds to cage 112 of FIGS. 1A, 1B and 1C. High-speed internal cable assembly 408 corresponds to any one of high-speed internal cable assembly 120 of FIG. 1A, high-speed internal cable assembly 140 of FIG. 1B or high-speed internal cable assembly 160 of FIG. 1C. Faceplate 453 corresponds to faceplate 153 of FIG. 1C.

In one embodiment, server platform 400 corresponds to a server blade. Chassis 410 may then correspond to or be included in a server blade enclosure configured to house the server blade.

In another embodiment, server platform 400 may include one or more server blade(s), e.g., server blade 401. In this embodiment, the substrate 402, the processor 404, the memory 406 and the high-speed cable assembly 408 are included in the server blade 401. The server blade 401 may be attached to chassis 410. Chassis 410 may then be included in a blade server enclosure configured to house a plurality of server blades, e.g., server blade 401. One or more of the video circuitry 430, the network interface circuitry 432 and/or the cooling fan 434 may be attached to chassis 410. In one example, the server blade 401 may include at least one of the persistent storage device 420 and/or the coprocessor circuitry 422. In another example, at least one of the persistent storage device 420 and/or the coprocessor circuitry 422 may be attached to the chassis 410.

Thus, a server platform may include a substrate, a processor, a memory and a high-speed internal cable, as described herein. In one embodiment, the server platform may correspond to a server blade. In another embodiment, the server platform may include one or more server blades.

“Circuitry,” as used in any embodiment herein, may comprise, for example, singly or in any combination, hardwired circuitry, programmable circuitry, state machine circuitry, logic and/or firmware that stores instructions executed by programmable circuitry. The circuitry may be embodied as an integrated circuit, such as an integrated circuit chip.

Memory 406 may include one or more of the following types of memory: semiconductor firmware memory, programmable memory, non-volatile memory, read only memory, electrically programmable memory, random access memory, flash memory, magnetic disk memory, and/or optical disk memory. Either additionally or alternatively memory may include other and/or later-developed types of computer-readable memory.

Network interface circuitry 432 may be capable of communicating using a selected packet switched network communications protocol. One example communications protocol may include an Ethernet communications protocol which may be capable permitting communication using a Transmission Control Protocol/Internet Protocol (TCP/IP). The Ethernet protocol may comply or be compatible with the Ethernet standard published by the Institute of Electrical and Electronics Engineers (IEEE) titled “IEEE Standard for Ethernet IEEE Std 802.3™-2015”, published September 2015 and/or earlier (e.g., IEEE Std 802.3-2012) and/or later and/or related versions of this standard.

In an embodiment, a mixed-signal connector, e.g., mixed-signal connector 118, 138, 158 and/or 300, may comply and/or be compatible with one or more connector specifications including, but not limited to, Small Form Factor (SFF) specification SFF-8665, titled Specification for QSFP+ 28 Gb/s 4× Pluggable Transceiver Solution (QSFP28), revision 1.9, released June 2015, by SFF TA (Technology Affiliate) TWG (Technical Working Group) of SNIA (Storage Networking Industry Association) and/or later and/or related versions of this specification, e.g., SFF-8672, titled Specification for QSFP+ 4× 28 Gb/s Connector (Style B), Rev 1.0, released January 2013, and/or SFF-8661, titled Specification for QSFP+ 4× Pluggable Module, Rev 2.3, released September 2014.

In another embodiment, a mixed-signal connector, e.g., mixed-signal connector 118, 138, 158 and/or 300, may comply and/or be compatible with one or more connector specifications including, but not limited to, CFP MSA (100G (100=C in Roman numerals) Form factor Pluggable Multi-Source Agreement) Hardware Specification, Rev. 1.4, released June 2010, by the CFP MSA organization, and/or later and/or related versions of this specification, e.g., CFP MSA CFP2 Hardware Specification, Rev. 1.0, released July 2013, and/or CFP MSA CFP4 Hardware Specification, Rev. 1.1, released March 2015.

In another embodiment, a mixed-signal connector, e.g., mixed-signal connector 118, 138, 158 and/or 300, may comply and/or be compatible with one or more connector specifications including, but not limited to, QSFP-DD Specification, titled: QSFP Double Density 8× Pluggable Transceiver, revision 1.0, released September 2015, by QSFP-DD MSA and/or later and/or related versions of this specification.

In another embodiment, a mixed-signal connector, e.g., mixed-signal connector 118, 138, 158 and/or 300, may comply and/or be compatible with one or more other and/or later-developed connector specifications including, for example, an OSFP (Octal Small Form Factor Pluggable) specification. OSFP may include eight high speed electrical lanes with a data rate of 400 Gbps (i.e., 8*50 Gbps).

In another embodiment, a mixed-signal connector, e.g., mixed-signal connector 118, 138, 158 and/or 300, may comply and/or be compatible with one or more connector specifications including, but not limited to, specification SFF-8431, titled Specifications for Enhanced Small Form Factor Pluggable Module SFP+, revision 4.1, released July 2009, and/or revision 4.1 addendum, released September 2013, managed by the SFF Committee of SNIA and/or later and/or related versions of this specification, e.g., SFF-8419, titled Specification for SFP+ Power and Low Speed Interface, Rev 1.3, released June 2015, and/or SFF-8418, titled Specification for SFP+ 10 Gb/s Electrical Interface, Rev 1.4, released July, 2015.

In some embodiments, a hardware description language (HDL) may be used to specify circuit and/or logic implementation(s) for the various logic and/or circuitry described herein. For example, in one embodiment the hardware description language may comply or be compatible with a very high-speed integrated circuits (VHSIC) hardware description language (VHDL) that may enable semiconductor fabrication of one or more circuits and/or logic described herein. The VHDL may comply or be compatible with IEEE Standard 1076-1987, IEEE Standard 1076.2, IEEE1076.1, IEEE Draft 3.0 of VHDL-2006, IEEE Draft 4.0 of VHDL-2008 and/or other versions of the IEEE VHDL standards and/or other hardware description standards.

In some embodiments, a Verilog hardware description language (HDL) may be used to specify circuit and/or logic implementation(s) for the various logic and/or circuitry described herein. For example, in one embodiment, the HDL may comply or be compatible with IEEE standard 62530-2011: SystemVerilog-Unified Hardware Design, Specification, and Verification Language, dated Jul. 7, 2011; IEEE Std 180™-2012: IEEE Standard for SystemVerilog-Unified Hardware Design, Specification, and Verification Language, released Feb. 21, 2013; IEEE standard 1364-2005: IEEE Standard for Verilog Hardware Description Language, dated Apr. 18, 2006 and/or other versions of Verilog HDL and/or SystemVerilog standards.

### EXAMPLES

Examples of the present disclosure include subject material such as a method, means for performing acts of the method, a device, or of an apparatus or system related to a mixed-signal connector and high-speed internal cable assembly, as discussed below.

### Example 1

According to this example, there is provided a mixed signal connector. The mixed signal connector includes a housing; a plurality of housing low-speed electrical contacts and a plurality of mixed-signal connector electrical contacts. The plurality of housing low-speed electrical contacts are to removably couple to a number of substrate electrical contacts. The plurality of mixed-signal connector electrical contacts are to removably couple to an external cable assembly. The plurality of mixed-signal connector electrical contacts include a first subset to fixedly couple to a high-speed internal cable, and a second subset coupled to the plurality of housing low-speed electrical contacts.

### Example 2

This example includes the elements of example 1, wherein the housing is to removably couple to a substrate.

### Example 3

This example includes the elements of example 1, wherein the housing is to removably couple to a receptacle.

### Example 4

This example includes the elements of example 1, wherein the plurality of housing low-speed electrical contacts are to removably couple to the number of substrate electrical contacts via a receptacle.

### Example 5

This example includes the elements of example 1, wherein the plurality of housing low-speed electrical contacts are to couple to a number of wires, the wires to removably couple to the number of substrate electrical contacts.

### Example 6

This example includes the elements according to any one of examples 1 to 5, wherein the first subset is to carry at least one high-speed signal with a data rate of greater than or equal to 10 Gigabits per second (Gbps) and the second subset is to carry at least one low-speed signal with a data rate of less than or equal to 1 Gbps.

### Example 7

This example includes the elements of example 6, wherein the second subset is further to carry power.

### Example 8

According to this example, there is provided a high-speed internal cable assembly. The high-speed internal cable assembly includes a high speed internal cable, a device connector and a mixed-signal connector. The high speed internal cable has a first end and a second end. The device connector is coupled to the high-speed internal cable at the first end. The mixed-signal connector is fixedly coupled to the high-speed internal cable at the second end. The mixed-signal connector includes a housing; a plurality of housing low-speed electrical contacts and a plurality of mixed-signal connector electrical contacts. The plurality of housing low-speed electrical contacts are to removably couple to a number of substrate electrical contacts. The plurality of mixed-signal connector electrical contacts are to removably couple to an external cable assembly. The plurality of mixed-signal connector electrical contacts include a first subset fixedly coupled to the high-speed internal cable, and a second subset coupled to the plurality of housing low-speed electrical contacts.

### Example 9

This example includes the elements of example 8, wherein the housing is to removably couple to a substrate.

### Example 10

This example includes the elements of example 8, wherein the housing is to removably couple to a receptacle.

### Example 11

This example includes the elements of example 8, wherein the plurality of housing low-speed electrical contacts are to removably couple to the number of substrate electrical contacts via a receptacle.

### Example 12

This example includes the elements of example 8, wherein the plurality of housing low-speed electrical contacts are to couple to a number of wires, the wires to removably couple to the number of substrate electrical contacts.

### Example 13

This example includes the elements according to any one of examples 8 to 12, wherein the high-speed internal cable and the first subset are to carry at least one high-speed signal with a data rate of greater than or equal to 10 Gigabits per second (Gbps) and the second subset is to carry at least one low-speed signal with a data rate of less than or equal to 1 Gbps.

### Example 14

This example includes the elements of example 13, wherein the second subset is further to carry power.

### Example 15

This example includes the elements according to any one of examples 8 to 12, wherein the high-speed internal cable is selected from the group including a twinaxial cable, a flexible printed circuit board and a flexible flat cable, the high-speed internal cable including at least one conductor pair.

### Example 16

This example includes the elements according to any one of examples 8 to 12, wherein the device connector is to couple to a processor connector.

### Example 17

This example includes the elements according to any one of examples 8 to 12, wherein the device connector is to couple to a switch connector.

### Example 18

This example includes the elements according to any one of examples 8 to 12, wherein the mixed-signal connector complies and/or is compatible with at least one of a Small Form Factor (SFF) specification SFF-8665, titled Specification for QSFP+ 28 Gb/s 4× Pluggable Transceiver Solution (QSFP28), revision 1.9, released June 2015, by SFF TA (Technology Affiliate) TWG (Technical Working Group) of SNIA (Storage Networking Industry Association) and/or SFF-8672, titled Specification for QSFP+ 4× 28 Gb/s Connector (Style B), Rev 1.0, released January 2013, and/or SFF-8661, titled Specification for QSFP+ 4× Pluggable Module, Rev 2.3, released September 2014.

### Example 19

This example includes the elements according to any one of examples 8 to 12, wherein the mixed-signal connector complies and/or is compatible with at least one of CFP MSA (100G (100=C in Roman numerals) Form factor Pluggable Multi-Source Agreement) Hardware Specification, Rev. 1.4, released June 2010, by the CFP MSA organization, and/or CFP MSA CFP2 Hardware Specification, Rev. 1.0, released July 2013, and/or CFP MSA CFP4 Hardware Specification, Rev. 1.1, released March 2015.

### Example 20

According to this example, there is provided a mixed-signal system. The mixed-signal system includes a substrate; a source device; and a high-speed internal cable assembly. The high-speed internal cable assembly includes a high speed internal cable, a device connector and a mixed-signal connector. The high speed internal cable has a first end and a second end. The device connector is coupled to the high-speed internal cable at the first end. The mixed-signal connector is fixedly coupled to the high-speed internal cable at the second end. The mixed-signal connector includes a housing; a plurality of housing low-speed electrical contacts and a plurality of mixed-signal connector electrical contacts. The plurality of housing low-speed electrical contacts are to removably couple to a number of substrate electrical contacts. The plurality of mixed-signal connector electrical contacts are to removably couple to an external cable assembly. The plurality of mixed-signal connector electrical contacts include a first subset fixedly coupled to the high-speed internal cable, and a second subset coupled to the plurality of housing low-speed electrical contacts.

### Example 21

This example includes the elements of example 20, wherein the housing is removably coupled to the substrate.

### Example 22

This example includes the elements of example 20, further including a receptacle fixedly coupled to the substrate, the housing removably coupled to the receptacle.

### Example 23

This example includes the elements of example 22, wherein the plurality of housing low-speed electrical contacts are removably coupled to the number of substrate electrical contacts via the receptacle.

### Example 24

This example includes the elements of example 20, wherein the plurality of housing low-speed electrical contacts are coupled to a number of wires, the wires removably coupled to the number of substrate electrical contacts.

### Example 25

This example includes the elements according to any one of examples 20 to 24, wherein the high-speed internal cable and the first subset are to carry at least one high-speed signal with a data rate of greater than or equal to 10 Gigabits per second (Gbps) and the second subset is to carry at least one low-speed signal with a data rate of less than or equal to 1 Gbps.

### Example 26

This example includes the elements of example 25, wherein the second subset is further to carry power.

### Example 27

This example includes the elements according to any one of examples 20 to 24, wherein the high-speed internal cable is selected from the group including a twinaxial cable, a flexible printed circuit board and a flexible flat cable, the high-speed internal cable including at least one conductor pair.

### Example 28

This example includes the elements according to any one of examples 20 to 24, wherein the source device is a processor and the device connector is coupled to a processor connector.

### Example 29

This example includes the elements according to any one of examples 20 to 24, wherein the source device is switch circuitry and the device connector is coupled to a switch connector.

### Example 30

This example includes the elements according to any one of examples 20 to 24, wherein the mixed-signal connector complies and/or is compatible with at least one of a Small Form Factor (SFF) specification SFF-8665, titled Specification for QSFP+ 28 Gb/s 4× Pluggable Transceiver Solution (QSFP28), revision 1.9, released June 2015, by SFF TA (Technology Affiliate) TWG (Technical Working Group) of SNIA (Storage Networking Industry Association) and/or SFF-8672, titled Specification for QSFP+ 4× 28 Gb/s Connector (Style B), Rev 1.0, released January 2013, and/or SFF-8661, titled Specification for QSFP+ 4× Pluggable Module, Rev 2.3, released September 2014.

### Example 31

This example includes the elements according to any one of examples 20 to 24, wherein the mixed-signal connector complies and/or is compatible with at least one of CFP MSA (100G (100=C in Roman numerals) Form factor Pluggable Multi-Source Agreement) Hardware Specification, Rev. 1.4, released June 2010, by the CFP MSA organization, and/or CFP MSA CFP2 Hardware Specification, Rev. 1.0, released July 2013, and/or CFP MSA CFP4 Hardware Specification, Rev. 1.1, released March 2015.

### Example 32

This example includes the elements according to any one of examples 20 to 24, further including a mechanical feature to removably mechanically couple the mixed-signal connector to the substrate.

### Example 33

This example includes the elements of example 32, wherein the mechanical feature includes a removable holddown mechanism and a removable fastener, the removable holddown mechanism selected from the group including a latch, a clip, a clamp, a strap and a bracket and the fastener is selected from the group including a screw, a clip, a tab.

### Example 34

This example includes the elements according to any one of examples 20 to 24, further including a cage to mitigate electromagnetic interference.

### Example 35

This example includes the elements according to any one of examples 20 to 24, wherein the substrate is a printed circuit board (PCB) including a plurality of conductive traces, each substrate electrical contact electrically coupled to a respective conductive trace.

### Example 36

According to this example, there is provided a server platform. The server platform includes a substrate; a processor; a memory; and a high-speed internal cable assembly. The high-speed internal cable assembly includes a high speed internal cable, a device connector and a mixed-signal connector. The high speed internal cable has a first end and a second end. The device connector is coupled to the high-speed internal cable at the first end. The mixed-signal connector is fixedly coupled to the high-speed internal cable at the second end. The mixed-signal connector includes a housing; a plurality of housing low-speed electrical contacts and a plurality of mixed-signal connector electrical contacts. The plurality of housing low-speed electrical contacts are to removably couple to a number of substrate electrical contacts. The plurality of mixed-signal connector electrical contacts are to removably couple to an external cable assembly. The plurality of mixed-signal connector electrical contacts include a first subset fixedly coupled to the high-speed internal cable, and a second subset coupled to the plurality of housing low-speed electrical contacts.

### Example 37

This example includes the elements of example 36, wherein the housing is removably coupled to the substrate.

### Example 38

This example includes the elements of example 36, further including a receptacle fixedly coupled to the substrate, the housing removably coupled to the receptacle.

### Example 39

This example includes the elements of example 38, wherein the plurality of housing low-speed electrical contacts are removably coupled to the number of substrate electrical contacts via the receptacle.

### Example 40

This example includes the elements of example 36, wherein the plurality of housing low-speed electrical contacts are coupled to a number of wires, the wires removably coupled to the number of substrate electrical contacts.

### Example 41

This example includes the elements according to any one of examples 36 to 40, wherein the high-speed internal cable and the first subset are to carry at least one high-speed signal with a data rate of greater than or equal to 10 Gigabits per second (Gbps) and the second subset is to carry at least one low-speed signal with a data rate of less than or equal to 1 Gbps.

### Example 42

This example includes the elements of example 41, wherein the second subset is further to carry power.

### Example 43

This example includes the elements according to any one of examples 36 to 40, wherein the high-speed internal cable is selected from the group including a twinaxial cable, a flexible printed circuit board and a flexible flat cable, the high-speed internal cable including at least one conductor pair.

### Example 44

This example includes the elements according to any one of examples 36 to 40, wherein the mixed-signal connector complies and/or is compatible with at least one of a Small Form Factor (SFF) specification SFF-8665, titled Specification for QSFP+ 28 Gb/s 4× Pluggable Transceiver Solution (QSFP28), revision 1.9, released June 2015, by SFF TA (Technology Affiliate) TWG (Technical Working Group) of SNIA (Storage Networking Industry Association) and/or SFF-8672, titled Specification for QSFP+ 4× 28 Gb/s Connector (Style B), Rev 1.0, released January 2013, and/or SFF-8661, titled Specification for QSFP+ 4× Pluggable Module, Rev 2.3, released September 2014.

### Example 45

This example includes the elements according to any one of examples 36 to 40, wherein the mixed-signal connector complies and/or is compatible with at least one of CFP MSA (100G (100=C in Roman numerals) Form factor Pluggable Multi-Source Agreement) Hardware Specification, Rev. 1.4, released June 2010, by the CFP MSA organization, and/or CFP MSA CFP2 Hardware Specification, Rev. 1.0, released July 2013, and/or CFP MSA CFP4 Hardware Specification, Rev. 1.1, released March 2015.

### Example 46

This example includes the elements according to any one of examples 36 to 40, further including a mechanical feature to removably mechanically couple the mixed-signal connector to the substrate.

### Example 47

This example includes the elements of example 46, wherein the mechanical feature includes a removable holddown mechanism and a removable fastener, the removable holddown mechanism selected from the group including a latch, a clip, a clamp, a strap and a bracket and the fastener is selected from the group including a screw, a clip, a tab.

### Example 48

This example includes the elements according to any one of examples 36 to 40, further including a cage to mitigate electromagnetic interference.

### Example 49

This example includes the elements according to any one of examples 36 to 40, wherein the substrate is a printed circuit board (PCB) including a plurality of conductive traces, each substrate electrical contact electrically coupled to a respective conductive trace.

### Example 50

This example includes the elements according to any one of examples 36 to 40, wherein the substrate, the processor, the memory and the high-speed cable assembly are included in a server blade.

### Example 51

This example includes the elements according to any one of examples 36 to 40, further including at least one of a persistent storage device and/or a coprocessor circuitry.

### Example 52

This example includes the elements of example 51, wherein the substrate, the processor, the memory, the high-speed cable assembly and the at least one of a persistent storage device and/or a coprocessor circuitry are included in a server blade.

### Example 53

This example includes the elements according to any one of examples 36 to 40, further including one or more of a video circuitry, a network interface circuitry and/or a cooling fan.

### Example 54

This example includes the elements of example 53, wherein the substrate, the processor, the memory, the high-speed cable assembly and the video circuitry, the network interface circuitry and/or the cooling fan are included in a server blade.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents.

Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

1. A mixed signal connector comprising:
a housing that includes a plurality of housing low-speed electrical contacts to removably couple to multiple substrate electrical contacts via a receptacle interposed between the housing and the multiple substrate electrical contacts; and
a plurality of mixed-signal connector electrical contacts to removably couple to an external cable assembly, the plurality of mixed-signal connector electrical contacts comprising:
a first subset to fixedly couple to a high-speed internal cable, and
a second subset to couple to the plurality of housing low-speed electrical contacts.

2. The mixed signal connector of claim 1, wherein the housing is to removably couple to a substrate via said receptacle.

3. (canceled)

4. (canceled)

5. (canceled)

6. The mixed signal connector of claim 1, wherein the first subset is to carry at least one high-speed signal with a data rate of greater than or equal to 10 Gigabits per second (Gbps) and the second subset is to carry at least one low-speed signal with a data rate of less than or equal to 1 Gbps and power.

7. A high-speed internal cable assembly comprising:
a high-speed internal cable having a first end and a second end;
a device connector coupled to the high-speed internal cable at the first end; and
a mixed-signal connector fixedly coupled to the high-speed internal cable at the second end, the mixed-signal connector comprising:
a housing having a plurality of housing low-speed electrical contacts to removably couple to multiple substrate electrical contacts via a receptacle interposed between the housing and the multiple substrate electrical contacts; and
a plurality of mixed-signal connector electrical contacts to removably couple to an external cable assembly, the plurality of mixed-signal connector electrical contacts comprising a first subset fixedly coupled to the high-speed internal cable, and a second subset coupled to the plurality of housing low-speed electrical contacts.

8. The high-speed internal cable assembly of claim 7, wherein the housing is to removably couple to a substrate via said receptacle.

9. (canceled)

10. (canceled)

11. The high-speed internal cable assembly of claim 7, wherein the high-speed internal cable and the first subset are to carry at least one high-speed signal with a data rate of greater than or equal to 10 Gigabits per second (Gbps) and the second subset is to carry at least one low-speed signal with a data rate of less than or equal to 1 Gbps and power.

12. The high-speed internal cable assembly of claim 7, wherein the high-speed internal cable is selected from the group comprising a twinaxial cable, a flexible printed circuit board and a flexible flat cable, the high-speed internal cable comprising at least one conductor pair.

13. The high-speed internal cable assembly of claim 7, wherein the device connector is to couple to a processor connector or to a switch connector.

14. The high-speed internal cable assembly of claim 7, wherein the mixed-signal connector complies and/or is compatible with at least one of a Small Form Factor (SFF) specification SFF-8665, titled Specification for QSFP+ 28 Gb/s 4× Pluggable Transceiver Solution (QSFP28), revision 1.9, released June 2015, by SFF TA (Technology Affiliate) TWG (Technical Working Group) of SNIA (Storage Networking Industry Association) and/or SFF-8672, titled Specification for QSFP+ 4× 28 Gb/s Connector (Style B), Rev 1.0, released January 2013, and/or SFF-8661, titled Specification for QSFP+ 4× Pluggable Module, Rev 2.3, released September 2014; OR at least one of CFP MSA (100G (100=C in Roman numerals) Form factor Pluggable Multi-Source Agreement) Hardware Specification, Rev. 1.4, released June 2010, by the CFP MSA organization, and/or CFP MSA CFP2 Hardware Specification, Rev. 1.0, released July 2013, and/or CFP MSA CFP4 Hardware Specification, Rev. 1.1, released March 2015.

15. A mixed-signal system comprising:
a substrate;
a receptacle fixedly coupled to the substrate;
a source device; and
a high-speed internal cable assembly comprising
a high-speed internal cable having a first end and a second end,
a device connector coupled to the high-speed internal cable at the first end, and
a mixed-signal connector fixedly coupled to the high-speed internal cable at the second end, the mixed-signal connector comprising a housing that includes a plurality of housing low-speed electrical contacts to removably couple to multiple substrate electrical contacts via the receptacle, and a plurality of mixed-signal connector electrical contacts to removably couple to the external cable assembly, the plurality of mixed-signal connector electrical contacts comprising a first subset fixedly coupled to the high-speed internal cable, and a second subset coupled to the plurality of housing low-speed electrical contacts;
wherein the receptacle is interposed between the housing and the multiple substrate electrical contacts.

16. (canceled)

17. (canceled)

18. (canceled)

19. The mixed signal system of claim 15, wherein the high-speed internal cable and the first subset are to carry at least one high-speed signal with a data rate of greater than or equal to 10 Gigabits per second (Gbps) and the second subset is to carry at least one low-speed signal with a data rate of less than or equal to 1 Gbps and power.

20. The mixed signal system of claim 15, wherein the high-speed internal cable is selected from the group comprising a twinaxial cable, a flexible printed circuit board and a flexible flat cable, the high-speed internal cable comprising at least one conductor pair.

21. The mixed signal system of claim 15, wherein the source device is a processor and the device connector is coupled to a processor connector, or the source device is switch circuitry and the device connector is coupled to a switch connector.

22. The mixed signal system of claim 15, wherein the mixed-signal connector complies and/or is compatible with at least one of a Small Form Factor (SFF) specification SFF-8665, titled Specification for QSFP+ 28 Gb/s 4× Pluggable Transceiver Solution (QSFP28), revision 1.9, released June 2015, by SFF TA (Technology Affiliate) TWG (Technical Working Group) of SNIA (Storage Networking Industry Association) and/or SFF-8672, titled Specification for QSFP+ 4× 28 Gb/s Connector (Style B), Rev 1.0, released January 2013, and/or SFF-8661, titled Specification for QSFP+4× Pluggable Module, Rev 2.3, released September 2014; OR at least one of CFP MSA (100G (100=C in Roman numerals) Form factor Pluggable Multi-Source Agreement) Hardware Specification, Rev. 1.4, released June 2010, by the CFP MSA organization, and/or CFP MSA CFP2 Hardware Specification, Rev. 1.0, released July 2013, and/or CFP MSA CFP4 Hardware Specification, Rev. 1.1, released March 2015.

23. The mixed signal system of claim 15, further comprising a mechanical feature to removably mechanically couple the mixed-signal connector to the substrate.

24. The mixed signal system of claim 23, wherein the mechanical feature comprises a removable holddown mechanism and a removable fastener, the removable holddown mechanism selected from the group comprising a latch, a clip, a clamp, a strap and a bracket and the fastener is selected from the group comprising a screw, a clip, a tab.

25. The mixed signal system of claim 15, wherein the substrate is a printed circuit board (PCB) comprising a plurality of conductive traces, each substrate electrical contact electrically coupled to a respective conductive trace.
